(19) United States
(12) Patent Application Publication
(10) Pub. No.: US 2026/0176751 A1
(43) Pub. Date: Jun. 25, 2026

(54) METHOD FOR FORMING ALUMINUM OXIDE

(71) Applicant: ASM IP Holding B.V., Almere (NL)

(72) Inventors: Patricio Eduardo Romero, Wilsele (BE); Charles Dezelah, Helsinki (FI); Eric James Shero, Phoenix, AZ (US); Jocelyn Kofi Bobbey, Phoenix, AZ (US); Petro Deminskyi, Espoo (FI); Michael Eugene Givens, Scottsdale, AZ (US)

(21) Appl. No.: 19/426,303

(22) Filed: Dec. 19, 2025

Related U.S. Application Data
(60) Provisional application No. 63/737,830, filed on Dec. 23, 2024.

(51) Int. Cl. C23C 16/40; C01F 7/02; C23C 16/455; H10P 14/60; H10P 14/692

(52) U.S. Cl. CPC C23C 16/403; C01F 7/02; C23C 16/45553; H10P 14/6339; H10P 14/668; H10P 14/69391

(57) ABSTRACT

A method of forming aluminum oxide on a substrate using a cyclical deposition process includes the following steps. There is a step (a) contacting the substrate with an aluminum alkyl precursor. There is a step (b) contacting the substrate with water or an alcohol and/or a step (c) contacting the substrate with an aluminum alkoxide or contacting the substrate with another aluminum alkyl precursor.

### CROSS-REFERENCE TO RELATED APPLICATIONS

The present application claims priority to and the benefit of U.S. Provisional Application No. 63/737,830, filed Dec. 23, 2024, the entirety of which is hereby incorporated by reference herein.

### FIELD

The present disclosure relates to semiconductor technology, and, in particular, to methods for forming aluminum oxide on a substrate.

### BACKGROUND

The scaling of semiconductor devices (such as logic devices and memory devices, for example) has led to significant improvements in the speed and density of integrated circuits. As structure dimensions shrink and aspect ratios increase, conventional techniques for small size and/or high aspect ratio devices (e.g., Fin Field Effect Transistors (“FinFET”), Gate-All-Around Field Effect Transistors (“GAA FET”), Dynamic Random Access Memory (“DRAM”) and Vertical NAND (“V-NAND”) structures) face significant challenges for future technology nodes. One challenge has been to find suitable ways of filling a gap, a void, or a seam included in a substrate.

Any discussion, including discussion of problems and solutions, set forth in this section has been included in this disclosure solely for the purpose of providing a context for the present disclosure. This discussion should not be taken as an admission that any or all of the information was known at the time the invention was made or otherwise constitutes prior art.

### BRIEF SUMMARY OF THE INVENTION

This summary may introduce a selection of concepts in a simplified form, which may be described in further detail below. This summary is not intended to necessarily identify key features or essential features of the claimed subject matter, nor is it intended to be used to limit the scope of the claimed subject matter.

One aspect of the present disclosure provides a method of forming aluminum oxide on a substrate, the method comprising: executing at least one deposition cycle, wherein the at least one deposition cycle comprises: (a) contacting the substrate with an aluminum alkyl precursor; and (b) contacting the substrate with water or an alcohol, thereby forming the aluminum oxide on the substrate.

In some embodiments, the substrate comprises a gap feature, and wherein the aluminum oxide fills the gap feature substantially without seams.

In some embodiments, the alcohol is represented by Formula (2):

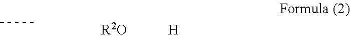

wherein R² is a C₁-C₁₀ alkyl group or a —Si—(R³)₃ group, and each R³ is independently a C₁-C₅ alkyl group.

In some embodiments, the alcohol is represented by one of the following formulae:

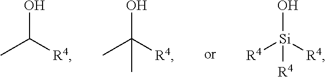

wherein R⁴ is H or a C₁-C₅ alkyl group.

In some embodiments, the at least one deposition cycle step (c) further comprises contacting the substrate with an aluminum alkoxide or contacting the substrate with another aluminum alkyl precursor.

In some embodiments, in step (b), the substrate is contacted with water, and, in step (c), aluminum alkoxide is contacted with the substrate.

In some embodiments, in step (b), the substrate is contacted with alcohol, and, in step (c), aluminum alkoxide is produced in-situ by a reaction of the aluminum alkyl precursor and alcohol.

In some embodiments, the step (c) further comprises introducing water during contacting the substrate with aluminum alkoxide.

In some embodiments, steps (a) and (b) are repeated more than once before step (c).

In some embodiments, steps (a), (b), and (c) are performed using an atomic layer deposition (ALD) process.

In some embodiments, steps (a) and (b) are performed using a deposition process and step (c) is performed using a chemical vapor deposition process.

In some embodiments, step (c) comprises contacting the substrate with an aluminum alkoxide, and wherein the aluminum alkoxide comprises a monomer unit represented by Formula (3):

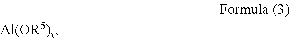

wherein x is an integer of 3 or 4;
each of R⁵ is independently hydrogen, a C₁-C₂₀ alkyl group, a C₂-C₁₀ alkenyl group, or a —Si—(R⁶)₃ group, provided that at least one R⁵ is not hydrogen, and when x is 4, two of R⁵ are linked to each other to form a saturated or unsaturated ring comprising Al; and
each of R⁶ is a C₁-C₅ alkyl group.

In some embodiments, the monomer unit is represented by one of the following formulae:

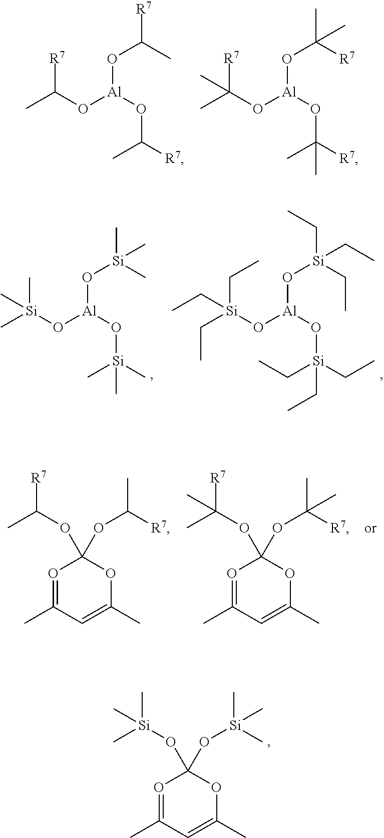

wherein each of R⁷ independently is a C₁-C₅ alkyl group.

In some embodiments, the aluminum alkoxide comprises one monomer unit represented by Formula (3), a dimer comprising two monomer units represented by Formula (3), or a combination thereof.

In some embodiments, step (c) comprises contacting the substrate with an aluminum alkoxide, and wherein a molar ratio of the aluminum alkoxide to the aluminum alkyl precursor is less than 1:1.

In some embodiments, the aluminum alkyl precursor comprises a monomer unit represented by Formula (1):

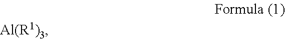

wherein each R¹ is independently a C₁-C₅ alkyl group.

In some embodiments, the aluminum alkyl precursor comprises one monomer unit represented by Formula (1), a dimer comprising two monomer units represented by Formula (1), or a combination thereof.

In accordance with another aspect, there is disclosed a method for forming aluminum oxide on a substrate using a cyclical deposition process, the method comprising: executing at least one deposition cycle, wherein the at least one deposition cycle comprises:
(a) contacting the substrate with an aluminum alkyl precursor; and (b) contacting the substrate with an aluminum alkoxide or another aluminum alkyl precursor.

In some embodiments, step (b) further comprises introducing water during contacting the substrate with the aluminum alkoxide.

In some embodiments, the aluminum alkoxide comprises a monomer unit represented by Formula (3):

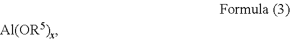

wherein x is an integer of 3 or 4;
each of R⁵ is independently hydrogen, a C₁-C₂₀ alkyl group, a C₂-C₁₀ alkenyl group, or a —Si—(R⁶)₃ group, provided that at least one R⁵ is not hydrogen, and when X is 4, two of R⁵ are linked to each other to form a saturated or unsaturated ring comprising Al; and each of R⁶ is a C₁-C₅ alkyl group.

In some embodiments, the monomer unit is represented by one of the following formulae:

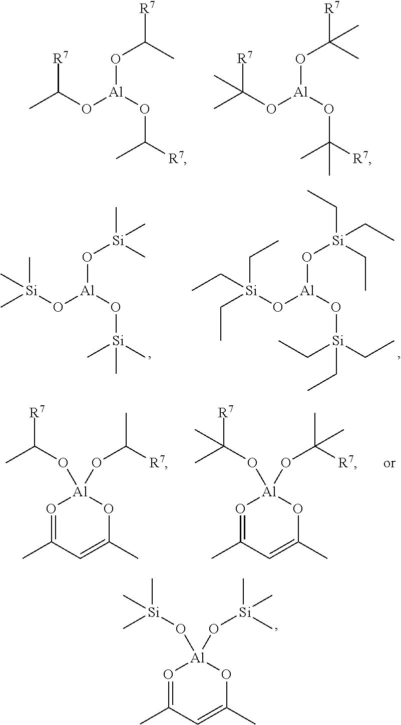

wherein each of R⁷ independently is a C₁-C₅ alkyl group.

In some embodiments, the aluminum alkoxide comprises a monomer comprising one monomer unit represented by Formula (3), a dimer comprising two monomer units represented by Formula (3), or a combination thereof.

In some embodiments, the aluminum alkyl precursor comprising a monomer unit represented by Formula (1):

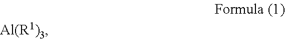

wherein each of R¹ is independently a C₁-C₈alkyl group.

In some embodiments, the aluminum alkyl precursor comprises a monomer comprising one monomer unit represented by Formula (1), a dimer comprising two monomer units represented by Formula (1), or a combination thereof.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWINGS

The present invention can be more fully understood by reading the subsequent detailed description and examples with references made to the accompanying drawings, wherein:

FIG. 1 is a flowchart of a method for forming aluminum oxide on a substrate according to an embodiment of the present disclosure;

FIG. 2 is a flowchart of a method for forming aluminum oxide on a substrate according to an embodiment of the present disclosure;

FIG. 3 is a flowchart of a method for forming aluminum oxide on a substrate according to another embodiment of the present disclosure; and

FIG. 4 is a flowchart of a method for forming aluminum oxide on a substrate according to another embodiment of the present disclosure.

### DETAILED DESCRIPTION

The following description is made for the purpose of illustrating the general principles of the disclosure and should not be taken in a limiting sense. The scope of the disclosure is determined by reference to the appended claims. Reference will now be made in detail to exemplary embodiments of the present disclosure, examples of which are illustrated in the accompanying drawings. Whenever possible, the same reference numbers are used in the drawings and descriptions to refer to the same or similar parts.

In the disclosure, the terms “about”, “equal to”, “equal” or “the same”, “substantially” or “approximately” usually indicates a value of a given value or range that varies within 20%, or a value of a given value or range that varies within 10%, within 5%, or within 3%, or within 2%, or within 1%, or within 0.5%. Further, any two numbers of a variable can constitute a workable range of the variable, and any ranges indicated may include or exclude the endpoints. Additionally, any values of variables indicated may refer to precise values or approximate values and include equivalents, and may refer to average, median, representative, majority, or the like.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁—Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

As used herein, the term “precursor” can refer to a compound that participates in the chemical reaction that produces another compound. In this disclosure, the term “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a noble gas.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, gaps, voids, seams and the like formed within or on at least a portion of the substrate. By way of example, a substrate can include at least one of bulk semiconductor material and an insulating or dielectric material layer overlying at least a portion of the bulk semiconductor material. The recesses, protrusions, gaps, voids, seams and the like may be in the bulk semiconductor material, the insulating and/or dielectric material layer on the bulk semiconductor material. In some embodiments, the recesses, protrusions, gaps, voids, seams and the like may be lateral and/or vertical to a normal direction of the bulk semiconductor material.

In this disclosure, the term “deposition process” as used herein may refer to the introduction of precursors into a reaction chamber to deposit a layer over a substrate. The term “cyclical deposition process” can refer to a sequential introduction of precursors into a reaction chamber to deposit a layer or a film over a substrate and includes processing techniques, such as atomic layer deposition (ALD), cyclical chemical vapor deposition (cyclical CVD), and hybrid cyclical deposition processes that include an ALD and a CVD.

One aspect of the present disclosure is providing a method of forming aluminum oxide on a substrate using a cyclical deposition process. A method of the present disclosure may include an atomic layer deposition (ALD) process, a cyclical chemical vapor deposition (cyclical CVD) process, or hybrid cyclical deposition processes that include an ALD and a CVD.

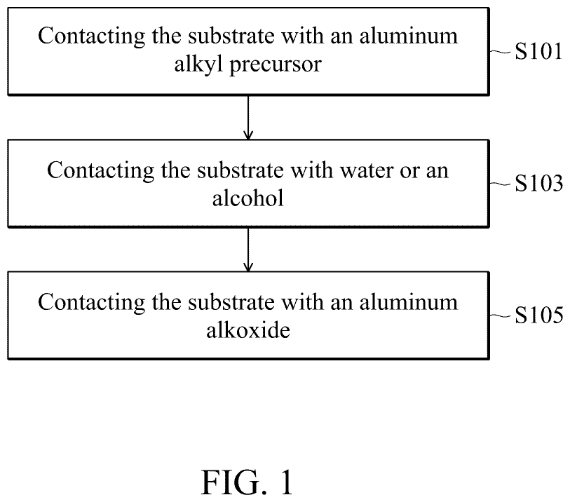

FIG. 1 is a flowchart of a method for forming aluminum oxide on a substrate using a cyclical deposition process in accordance with one aspect of the present invention. As shown in FIG. 1, the method includes a step S101 of contacting the substrate with an aluminum alkyl precursor and a step S103 of contacting the substrate with water or an alcohol. In some embodiments, step S101 and step S103 may be performed using an atomic layer deposition process. A deposition cycle including step S101 and step S103 may be performed one or more times until a sufficient amount of aluminum oxide is deposited or a gap in the substrate is filled. In some embodiments, step S101 and/or step S103 may be performed more than one time, but the disclosure is not limited thereto. In some embodiments, of step S101 and step S103, one may be performed more than once and the other may be performed just once.

Step S101 and step S103 may be performed in any suitable order or simultaneously. In some embodiments, step S103 of contacting the substrate with water or an alcohol may be performed after step S101 of contacting the substrate with an aluminum alkyl precursor, but the disclosure is not limited thereto. In some embodiments, step S103 of contacting the substrate with water or an alcohol may be performed before step S101 of contacting the substrate with an aluminum alkyl precursor. In some embodiments, step S101 of contacting the substrate with an aluminum alkyl precursor and step S103 of contacting the substrate with water or an alcohol may be performed simultaneously.

The methods of the present disclosure are performed on a substrate. In some embodiments, each step of the method may be performed on the same surface of the substrate. In one embodiment, step S101 of contacting the substrate with an aluminum alkyl precursor and step S103 of contacting the substrate with water or an alcohol may be performed on the same surface of the substrate, but the disclosure is so not limited thereto. The substrate may include any suitable material(s). In some embodiments, the substrate may include a monocrystalline silicon wafer, monocrystalline germanium wafers, gallium arsenide wafers, quartz, sapphire, glass, steel, aluminum, silicon-on-insulator substrates, plastics, or the like, but the disclosure is not limited thereto.

In some embodiments, the substrate may include a gap feature. The gap feature may be lateral and/or vertical to a normal direction of the bulk semiconductor material. The gap feature may have a depth of at least 5 nm to at most 500 nm, a width of at least 10 nm to at most 10,000 nm, and/or a length of at least 10 nm to at most 10,000 nm. In some embodiments, the gap feature may have a depth of at least 10 nm to at most 250 nm, or from at least 20 nm to at most 200 nm, or from at least 50 nm to at most 150 nm, or from at least 100 nm to at most 150 nm. In some embodiments, the gap feature may have a width of at least 20 nm to at most 5,000 nm, or from at least 40 nm to at most 2,500 nm, or from at least 80 nm to at most 1,000 nm, or from at least 100 nm to at most 500 nm, or from at least 150 nm to at most 400 nm, or from at least 200 nm to at most 300 nm. In some embodiments, the gap feature may have a length of at least 20 nm to at most 5,000 nm, or from at least 40 nm to at most 2,500 nm, or from at least 80 nm to at most 1,000 nm, or from at least 100 nm to at most 500 nm, or from at least 150 nm to at most 400 nm, or from at least 200 nm to at most 300 nm. The aluminum oxide formed from a method of the present disclosure can fill the gap substantially without seams (e.g., no gap having a length of approximately 5 nm or greater).

The aluminum alkyl precursor in contact with the substrate in step S101 may be an aluminum alkyl, including a monomer unit represented by Formula (1):

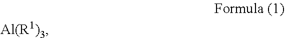

wherein each of R¹ independently is a C₁-C₅ alkyl group. In some embodiments, the aluminum alkyl precursor may include a monomer including one monomer unit represented by Formula (1), a dimer including two monomer units represented by Formula (1), or a combination thereof.

In some embodiments, the aluminum alkyl precursor may comprise an aluminum alkyl including a monomer unit including a tert-butyl group which is represented by Formula (1-1):

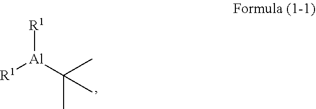

wherein each of R¹ independently is a C₁-C₅ alkyl group. In some embodiments, the aluminum alkyl precursor may include a monomer including one monomer unit represented by Formula (1-1), a dimer including two monomer units represented by Formula (1-1), or a combination thereof.

The term “C₁-C₅ alkyl group” used herein refers to a linear, branched, or cyclic aliphatic hydrocarbon monovalent group having 1 to 5 carbon atoms in the main carbon chain. Examples of the C₁-C₅ alkyl group include, but are not limited to a methyl group, an ethyl group, a propyl group, an iso-butyl group, a sec-butyl group, a tert-butyl group, a pentyl group, or a cyclopropyl group.

In some embodiments, the aluminum alkyl precursor used in step S101 may comprise trimethylaluminum (TMA), an aluminum alkyl including a tert-butyl group or a combination thereof, but the present disclosure is not limited thereto. In an embodiment where step S101 is performed more than one time, the aluminum alkyl precursor used in two steps S101 may be different from each other. In some embodiments, the aluminum alkyl precursor used in one step S101 may be trimethylaluminum, and the aluminum alkyl precursor used in other step S101 may be an aluminum alkyl including a tert-butyl group.

In step S101, the aluminum alkyl precursor may be introduced in a pulse form to contact with the substrate. In some embodiments, a pulse duration for the aluminum alkyl precursor may be from at least 0.1 s (seconds) to at most 1000 s, or from at least 0.2 s to at most 500 s, or from at least 0.5 s to at most 200 s, or from at least 1.0 s to at most 100 s, or from at least 2 s to at most 50 s, or from at least 5 s to at most 20 s.

In some embodiments, the alcohol contacted with the substrate in step S103 may have a structure represented by Formula (2):

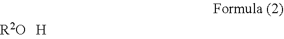

wherein R² is a C₁-C₁₀ alkyl group or a —Si—(R³)₃ group, each of R³ independently is a C₁-C₅ alkyl group. The definition of the term “C₁-C₂₀ alkyl group” used here is similar as the definition of the term “C₁-C₅ alkyl group” with the exception of the larger number of possible carbon atoms.

In some embodiments, the alcohol is represented by one of the following formulae:

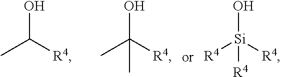

wherein R⁴ is H or a C₁-C₅ alkyl group. In some embodiments, R⁴ may be a methyl group.

In some embodiments, in step S103, an alcohol may be introduced in a pulse form to contact the substrate. In some embodiments, a pulse duration for water or the alcohol may be from at least 0.1 s (second) to at most 1000 s, or from at least 0.2 s to at most 500 s, or from at least 0.5 s to at most 200 s, or from at least 1.0 s to at most 100 s, or from at least 2 s to at most 50 s, or from at least 5 s to at most 20 s.

Step S101 and step S103 may be performed at a substrate temperature of less than 800° C. In some embodiments, step S101 and step S103 may be performed at a substrate temperature of at least 50° C. to at most 500° C., or of at least 100° C. to at most 300° C. In some embodiments, step S101 and step S103 may be performed at a substrate temperature of at least −25° C. to at most 300° C., or of at least 0° C. to at most 250° C., or of at least 25° C. to at most 200° C., or of at least 50° C. to at most 150° C., or of at least 75° C. to at most 125° C. The step S103 may be performed at the same or a different substrate temperature than that at which step S101 is performed.

In some embodiments, step S101 and step S103 may be performed at a pressure of at most 10.0 Torr. In some embodiments, step S101 and step S103 may be performed at a pressure of at most 5.0 Torr, or of at most 3.0 Torr, or of at most 2.0 Torr, or of at most 1.0 Torr, or of at most 0.1 Torr, or of at most 10⁻² Torr, or of at most 10⁻³ Torr, or of at most 10⁻⁴ Torr, or of at most 10⁻⁵ Torr, or of at least 0.1 Torr to at most 10 Torr, or of at least 0.2 Torr to at most 5 Torr, or of at least 0.5 Torr to at most 2.0 Torr. The step S103 may be performed at the same pressure as step S101 or at different pressure.

In some embodiments, the method may further include step S105 of contacting the substrate with an aluminum alkoxide. For example, in embodiments where the aluminum alkyl precursor contacted with the substrate in step S101 includes trimethylaluminum, the method may further include step S105 of contacting the substrate with an aluminum alkoxide as shown in FIG. 1.

Step S105 may be performed after step S101 or step S103, but the disclosure is not limited thereto. In some embodiments, step S105 may be performed between step S101 or step S103. In other embodiments, step S105 may be performed at the same time as step S101 and/or step S103.

In some embodiments, step S105 may be performed using an atomic layer deposition process or a chemical vapor deposition process. In some embodiments, step S101, step S103, and step S105 may be performed using an atomic layer deposition process. In some embodiments, step S101 and step S103 may be performed using an atomic layer deposition process and step S105 may be performed using a chemical vapor deposition process.

A deposition cycle including step S101, step S103, and step S105 may be performed one or more times until a sufficient amount of aluminum oxide is deposited on the substrate or the gap is filled. Furthermore, in each deposition cycle, each of step S101, step S103, and step S105 may be performed one or more times. In some embodiments, step S101, step S103, and step S105 may each be performed more than once per deposition cycle. In some embodiments, step S101 and step S103 may be repeated more than once (e.g., 2 or 3 or 4 times) before step S105 in one deposition cycle. In other embodiments, step S105 may be performed more than once (e.g., 2, 3, or 4 times) in one deposition cycle.

In some embodiments, the aluminum alkoxide contacted with the substrate in step S105 may include a monomer unit represented by Formula (3):

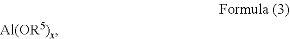

wherein x is an integer of 3 or 4;
wherein each of R⁵ is independently hydrogen, a C₁-C₂₀ alkyl group, a C₂-C₁₀ alkenyl group, or a —Si—(R⁶)₃ group, provided that at least one R⁵ is not hydrogen, and when x is 4, two of R⁵ are linked to each other to form a saturated or unsaturated ring comprising Al (that is, a bidentate oxygen-based complex moiety); and
each of R⁶ is a C₁-C₅ alkyl group. In some embodiments, the aluminum alkoxide may include a monomer including one monomer unit represented by Formula (3), a dimer including two monomer units represented by Formula (3), or a combination thereof.

As used herein, the term “C₂-C₁₀ alkenyl group” refers to a linear, branched, or cyclic aliphatic hydrocarbon monovalent group having 2 to 10 carbon atoms and at least one carbon-carbon double bond in the main carbon chain. Non-limiting examples of C₂-C₁₀ alkenyl group include, but are not limited to, an ethenyl group, a propenyl group, an isobutenyl group, a sec-butenyl group, a tert-butenyl group, a pentenyl group, an isopentenyl group, a hexenyl group, a decenyl group, and a cyclobutenyl group.

In some embodiments, the monomer unit may be represented by one of the following formulae:

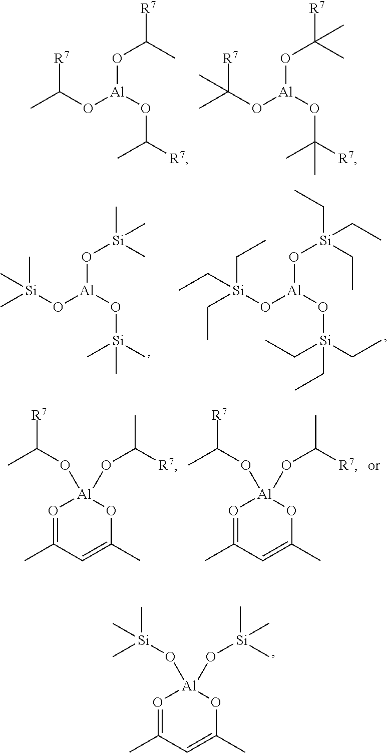

wherein each of R⁷ independently is a C₁-C₅ alkyl group.

In some embodiments, aluminum alkoxide clusters may be formed on the substrate by controlled hydrolysis. The clusters can fill a gap feature in the substrate and, under equilibrium conditions, can further condense to form a substantially seamless aluminum oxide fill features. In some embodiments, the molar ratio of the aluminum alkoxide contacted with the substrate in step S105 to the aluminum alkyl precursor contacted with the substrate in step S101 is less than 1:1.

In some embodiments, step S105 may be performed at a substrate temperature of less than 800° C. In some embodiments, step S105 may be performed at a substrate temperature of at least −25° C. to at most 800° C., or of at least 0° C. to at most 700° C., or of at least 25° C. to at most 600° C., or of at least 50° C. to at most 400° C., or of at least 75° C. to at most 200° C., or of at least 100° C. to at most 150° C. Step S105 may be performed at the same substrate temperature as step S103 or step S101, or at a different temperature.

In some embodiments, step S105 may be performed at a pressure of at most 10.0 Torr. In some embodiments, step S105 may be performed at a pressure of at most 5.0 Torr, or of at most 3.0 Torr, or of at most 2.0 Torr, or of at most 1.0 Torr, or of at most 0.1 Torr, or of at most 10⁻² Torr, or of at most 10⁻³ Torr, or of at most 10⁻⁴ Torr, or of at most 10⁻⁵ Torr, or of at least 0.1 Torr to at most 10 Torr, or of at least 0.2 Torr to at most 5 Torr, or of at least 0.5 Torr to at most 2.0 Torr. The step S105 may be performed at the same or a different pressure than that at which step S103 or step S101 is performed.

In some embodiments, the methods of the present disclosure may further include purging steps between each step to remove any excess precursor, reactants, materials, and/or reaction by-products. In particular embodiments, the methods of the present disclosure may further include a first purging step between step S101 and step S103, and/or a second purging step between step S103 and step S105. In some embodiments, each purging step may include introducing an inert or substantially inert gas into the reaction chamber between any two steps.

The methods of the present disclosure can form aluminum oxide on a substrate by a cyclical deposition process, such as an atomic layer deposition, a cyclical chemical vapor deposition, or a hybrid cyclical deposition processes that include an ALD and a CVD. In some embodiments, the aluminum oxide formed by a method as described herein may fill a gap in a substrate substantially without seams. The methods of the present disclosure can be advantageously used in the field of integrated circuit manufacture.

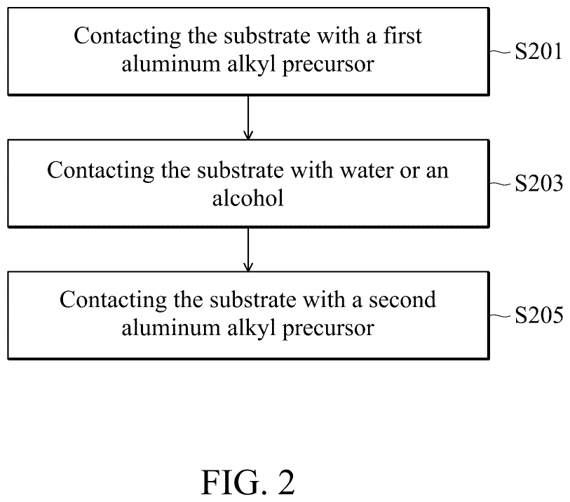

For a better understanding, some embodiments of the present disclosure will be further described below with reference to FIGS. 2-4.

FIG. 2 is a flowchart of a method for forming aluminum oxide on a substrate using a cyclical deposition process according to an embodiment of the present disclosure. As shown in FIG. 2, the method includes a step S201 of contacting the substrate with a first aluminum alkyl precursor, a step S203 of contacting the substrate with water or an alcohol, and a step S205 of contacting the substrate with a second aluminum alkyl precursor, wherein the first aluminum alkyl precursor may include an aluminum alkyl including a tert-butyl group. However, in some embodiments, step S205 may be omitted.

In some embodiments, step S201, step S203, and step S205 may be performed in any suitable order or simultaneously. For example, in some embodiments, step S203 of contacting the substrate with water or an alcohol may be performed before step S201 of contacting the substrate with a first aluminum alkyl precursor, and in some embodiments, step S205 of contacting the substrate with a second aluminum alkyl precursor may be performed before step S201 of contacting the substrate with a first aluminum alkyl precursor. In other embodiments, step S201 of contacting the substrate with a first aluminum alkyl precursor and step S203 of contacting the substrate with water or an alcohol may be performed simultaneously. In further embodiments, step S203 of contacting the substrate with water or an alcohol and step S205 of contacting the substrate with a second aluminum alkyl precursor may be performed simultaneously.

A deposition cycle including step S201, S203, and step S205 may be performed one or more times until a sufficient amount of aluminum oxide is deposited or the gap is filled. In some embodiments, each of step S201, step S203, and step S205 may be performed more than one time, but the disclosure is not limited thereto. In some embodiments, step S201 may be performed once and step S203 and step S205 may be performed more than once.

In some embodiments, each step S201 and step S205 may be performed simultaneously with step S203, and step S201 and step S205 may alternatively be performed more than one time. In some embodiments, each step S201 and step S205 may be performed simultaneously with step S203, step S205 may be performed more than one time, and step S201 may be performed after step S205 to complete the method. In some embodiments, each step S201 and step S205 may be performed simultaneously with step S203, step S205 may be repeated more than one time, and step S201 and step S205 may alternatively be performed more than once after the repeated step S205 to complete the method.

The aluminum alkyl including a tert-butyl group may include ^{t}Bu₂AlMe (which may exist in a dimer form, i.e. Al₂(^{t}Bu)₄Me₂), ^{t}Bu₃Al or a combination thereof, but the disclosure is not limited thereto. While not wishing to be bound by theory, it is believed that ^{t}Bu₂AlMe may be bridged by methyl groups to form a solid extended polymer. In the solid extended polymer, there are two molecules in a unit cell, each of which are part of two parallel and independent polymer chains. ^{t}Bu₂AlMe has a high degree of self-association at the molecular level, which may result in better gap-filling behavior. ^{t}Bu₂AlMe clusters may be formed upon controlled hydrolysis.

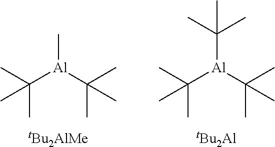

A pulse duration for the first aluminum alkyl precursor may be from at least 0.1 s to at most 1000 s, or from at least 0.2 s to at most 500 s, or from at least 0.5 s to at most 200 s, or from at least 1.0 s to at most 100 s, or from at least 2 s to at most 50 s, or from at least 5 s to at most 20 S.

After initial surface reaction with —OH functionalities, the aluminum alkyl including a tert-butyl group can act as an anchor for longer oligomers/dimers/trimers, resulting in more effective deposition or flow-like behavior. The —OH functionalities can be derived from water or from the alcohol that was in contact with the substrate in step S203. The alcohol that was in contact with the substrate in step S203 may have a structure represented by Formula (2) above.

A pulse duration for water or the alcohol may be from at least 0.1 s to at most 1000 s, or from at least 0.2 s to at most 500 s, or from at least 0.5 s to at most 200 s, or from at least 1.0 s to at most 100 s, or from at least 2 s to at most 50 s, or from at least 5 s to at most 20 s.

In some embodiment, the alcohol is represented by one of the following formulae:

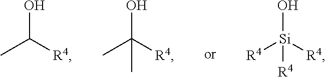

wherein R⁴ is H or a C₁-C₅ alkyl group. In some embodiments, R⁴ may be a methyl group.

The second aluminum alkyl precursor that was in contact with the substrate in step S203 may be an aluminum alkyl represented by Formula (1) (Al(R¹)₃) described above. The second aluminum alkyl precursor may be different from the first aluminum alkyl precursor. In some embodiments, the second aluminum alkyl precursor may include trimethylaluminum (TMA).

In some embodiments, a pulse duration for the second aluminum alkyl precursor may be from at least 0.1 s to at most 1000 s, or from at least 0.2 s to at most 500 s, or from at least 0.5 s to at most 200 s, or from at least 1.0 s to at most 100 s, or from at least 2 s to at most 50 s, or from at least 5 s to at most 20 s. The pulse duration for the second aluminum alkyl precursor may be the same or different from the pulse duration for the first aluminum alkyl precursor.

The substrate temperature and the pressure used in step S201 and S205 may be the same as step S101, and the substrate temperature and the pressure used in step S203 may be the same as step S103. It is therefore not repeated here.

In some embodiments, the method of the present disclosure may further include purging steps between each step to remove any excess precursor, reactants, materials, and/or reaction by-products. In particular, the method of the present disclosure may further include a first purging step between step S201 and step S203, and/or a second purging step between step S203 and step S205. In some embodiments, each purging step may include introducing an inert or substantially inert gas into the reaction chamber between any two steps.

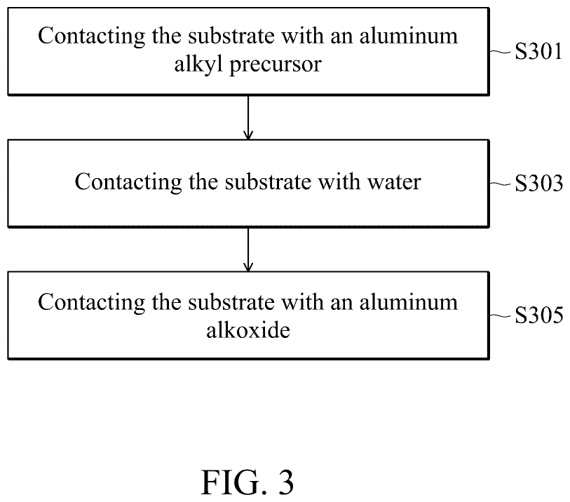

FIG. 3 is a flowchart of a method for forming aluminum oxide on a substrate using a cyclical deposition process according to another embodiment of the present disclosure. As shown in FIG. 3, the method includes a step S301 of contacting the substrate with an aluminum alkyl precursor, a step S303 of contacting the substrate with water, and a step S305 of contacting the substrate with an aluminum alkoxide. In some embodiments, the aluminum alkyl precursor contacted the substrate in step S301 includes trimethylaluminum (TMA).

In some embodiments, step S301, step S303, and step S305 may be performed in any suitable order or simultaneously. For example, in some embodiments, step S303 of contacting the substrate with water may be performed before step S301 of contacting the substrate with an aluminum alkyl precursor, and in some embodiments, step S305 of contacting the substrate with an aluminum alkoxide may be performed before step S301 of contacting the substrate with an aluminum alkyl precursor. In other embodiments, step S301 of contacting the substrate with an aluminum alkyl precursor and step S303 of contacting the substrate with water may be performed simultaneously. In further embodiments, step S303 of contacting the substrate with water and step S305 of contacting the substrate with an aluminum alkoxide may be performed simultaneously.

A deposition cycle including step S301, S303, and step S305 may be performed one or more times until a sufficient amount of aluminum oxide is deposited or the gap is filled. In some embodiments, each of step S301, step S303, and step S305 may be performed more than one time, but the disclosure is not limited thereto. In some embodiments, step S301 may be performed once and step S303 and step S305 may be performed more than once.

In some embodiments, the aluminum alkoxide contacted with the substrate in step S305 is introduced to contact the substrate as an independent source. In some embodiments, the molar ratio of the aluminum alkoxide contacted with the substrate in step S305 to the aluminum alkyl precursor contacted the substrate in step S301 is less than 1:1.

In some embodiments, the aluminum alkoxide may be introduced in a pulse form for from at least 0.1 s to at most 1000 s, or from at least 0.2 s to at most 500 s, or from at least 0.5 s to at most 200 s, or from at least 1.0 s to at most 100 s, or from at least 2 s to at most 50 s, or from at least 5 s to at most 20 s. Steps S301-S305 are substantially the same as steps S103-S105. The details of the method shown in FIG. 3 are not repeated here.

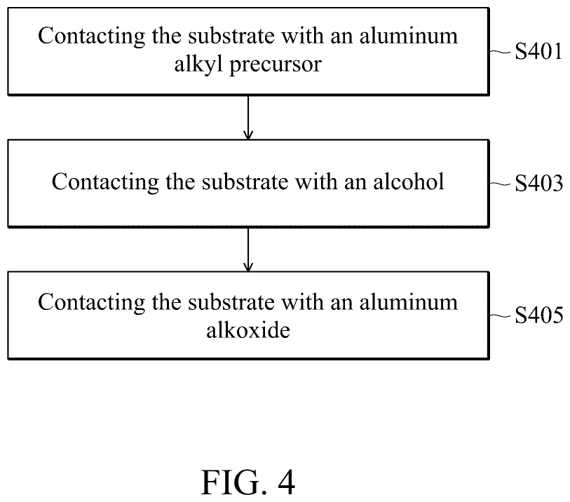

FIG. 4 is a flowchart of a method for forming aluminum oxide on a substrate using a cyclical deposition process according to another embodiment of the present disclosure. As shown in FIG. 4, the method includes a step S401 of contacting the substrate with an aluminum alkyl precursor, a step S403 of contacting the substrate with an alcohol, and a step S405 of contacting the substrate with an aluminum alkoxide. In some embodiments, the aluminum alkyl precursor contacted the substrate in step S401 includes trimethylaluminum (TMA), and the alcohol contacted with the substrate in step S403 may have a structure represented by Formula (2) above.

In some embodiments, step S401, step S403, and step S405 may be performed in any suitable order or simultaneously. For example, in some embodiments, step S403 of contacting the substrate with an alcohol may be performed before step S401 of contacting the substrate with an aluminum alkyl precursor, and in some embodiments, step S405 of contacting the substrate with an aluminum alkoxide may be performed before step S401 of contacting the substrate with an aluminum alkyl precursor. In other embodiments, step S401 of contacting the substrate with an aluminum alkyl precursor and step S403 of contacting the substrate with an alcohol may be performed simultaneously. In further embodiments, step S403 of contacting the substrate with an alcohol and step S405 of contacting the substrate with an aluminum alkoxide may be performed simultaneously.

A deposition cycle including step S401, S403, and step S405 may be performed one or more times until a sufficient amount of aluminum oxide is deposited or the gap is filled. In some embodiments, each of step S401, step S403, and step S405 may be performed more than one time, but the disclosure is not limited thereto. In some embodiments, step S401 may be performed once and step S403 and step S405 may be performed more than once.

In some embodiments, the aluminum alkoxide contacted with the substrate in step S405 is produced in situ by a reaction of the aluminum alkyl precursor and the alcohol. In some embodiments, the method may further include introducing water while the substrate is contacted with the aluminum alkoxide. Steps S401-S405 are substantially the same as steps S103-S105. The details of the method shown in FIG. 4 are not repeated here.

The methods of the present disclosure shown in FIGS. 2-4 above can form aluminum oxide on a substrate by a cyclical deposition process, such as an atomic layer deposition, a cyclical chemical vapor deposition, and a hybrid cyclical deposition processes that include an ALD and a CVD. In some embodiments, the aluminum oxide formed by the method of the present disclosure may fill one or more gaps in the substrate substantially without seams. Methods of the present disclosure can be advantageously used in the field of integrated circuit manufacture.

Although embodiments of the present disclosure and the advantages thereof have been disclosed as described above, it should be understood that changes, substitutions and modifications may be made without departing from the spirit and scope of the disclosure. In addition, the protection scope of the present disclosure is not limited to the processes, machines, fabrications, compositions, devices, methods and steps in the specific embodiments described in the specification. According to the embodiments of the present disclosure, a person of ordinary skill in the art may understand that current or future processes, machines, fabrications, compositions, devices, methods and steps capable of performing substantially the same functions or achieving substantially the same results may be used in the embodiments of the present disclosure. Therefore, the protection scope of the present disclosure includes the above-mentioned processes, machines, fabrications, compositions, devices, methods and steps. In addition, features of different embodiments may be used together arbitrary as long as they do not violate the spirit of the disclosure or conflict with each other. Each claim constitutes an individual embodiment, and the protection scope of the present disclosure includes the combination of the claims and embodiments.

1. A method for forming aluminum oxide on a substrate, the method comprising:
executing at least one deposition cycle, wherein the at least one deposition cycle comprises:
(a) contacting the substrate with an aluminum alkyl precursor; and
(b) contacting the substrate with water or an alcohol,
thereby forming the aluminum oxide on the substrate.

2. The method of claim 1, wherein the substrate comprises a gap feature, and wherein the aluminum oxide fills the gap feature substantially without seams.

3. The method of claim 1, wherein the alcohol is represented by Formula (2): 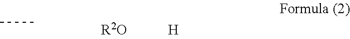
wherein R² is a C₁-C₁₀ alkyl group or a —Si—(R³)₃ group, and each R³ is independently a C₁-C₅ alkyl group.

4. The method of claim 3, wherein the alcohol is represented by one of the following formulae: 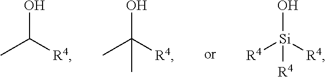
wherein R⁴ is H or a C₁-C₅ alkyl group.

5. The method of claim 1, wherein the at least one deposition cycle step (c) further comprises contacting the substrate with an aluminum alkoxide or contacting the substrate with another aluminum alkyl precursor.

6. The method of claim 5, wherein in step (b), the substrate is contacted with water, and, in step (c), aluminum alkoxide is contacted with the substrate.

7. The method of claim 5, wherein, in step (b), the substrate is contacted with alcohol, and, in step (c), aluminum alkoxide is produced in-situ by a reaction of the aluminum alkyl precursor and alcohol.

8. The method of claim 5, wherein the step (c) further comprises introducing water during contacting the substrate with aluminum alkoxide.

9. The method of claim 5, wherein steps (a) and (b) are repeated more than once before step (c).

10. The method of claim 5, wherein the steps (a), (b), and (c) are performed using an atomic layer deposition (ALD) process.

11. The method of claim 5, wherein steps (a) and (b) are performed using a deposition process and step (c) is performed using a chemical vapor deposition process.

12. The method of claim 5, wherein step (c) comprises contacting the substrate with an aluminum alkoxide, and wherein the aluminum alkoxide comprises a monomer unit represented by Formula (3): 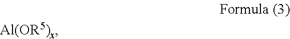
wherein x is an integer of 3 or 4;
each of R⁵ is independently hydrogen, a C₁-C₂₀ alkyl group, a C₂-C₁₀ alkenyl group, or a —Si—(R⁶)₃ group, provided that at least one R⁵ is not hydrogen, and when x is 4, two of R⁵ are linked to each other to form a saturated or unsaturated ring comprising Al; and
each of R⁶ is a C₁-C₅ alkyl group.

13. The method of claim 12, wherein the monomer unit is represented by one of the following formulae: 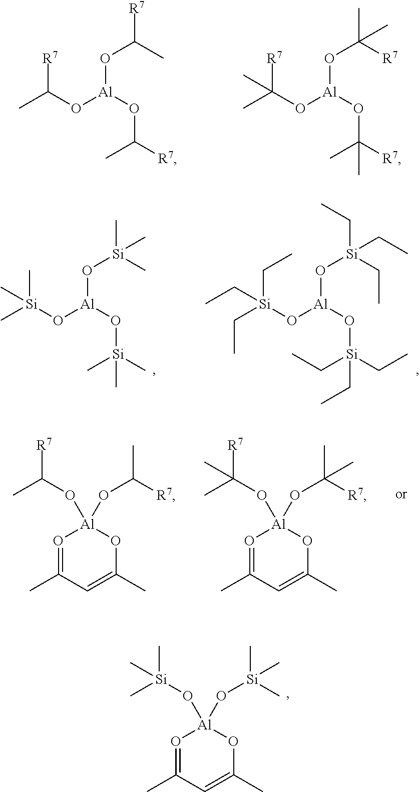
wherein each of R⁷ independently is a C₁-C₅ alkyl group.

14. The method of claim 12, wherein the aluminum alkoxide comprises one monomer unit represented by Formula (3), a dimer comprising two monomer units represented by Formula (3), or a combination thereof.

15. The method of claim 5, wherein step (c) comprises contacting the substrate with an aluminum alkoxide, and wherein a molar ratio of the aluminum alkoxide to the aluminum alkyl precursor is less than 1:1.

16. The method of claim 1, wherein the aluminum alkyl precursor comprises a monomer unit represented by Formula (1): 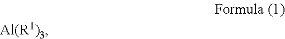
wherein each R¹ is independently a C₁-C₈alkyl group.

17. The method of claim 16, wherein the aluminum alkyl precursor comprises one monomer unit represented by Formula (1), a dimer comprising two monomer units represented by Formula (1), or a combination thereof.

18. A method for forming aluminum oxide on a substrate using a cyclical deposition process, the method comprising:
executing at least one deposition cycle, wherein the at least one deposition cycle comprises:
(a) contacting the substrate with an aluminum alkyl precursor; and
(b) contacting the substrate with an aluminum alkoxide or another aluminum alkyl precursor.

19. The method of claim 18, wherein step (b) further comprises introducing water during contacting the substrate with the aluminum alkoxide.

20. The method of claim 18, wherein the aluminum alkoxide comprises a monomer unit represented by Formula (3): 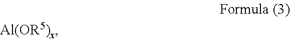
wherein x is an integer of 3 or 4;
each of R⁵ is independently hydrogen, a C₁-C₂₀ alkyl group, a C₂-C₁₀ alkenyl group, or a —Si—(R⁶)₃ group, provided that at least one R⁵ is not hydrogen, and when X is 4, two of R⁵ are linked to each other to form a saturated or unsaturated ring comprising Al; and
each of R⁶ is a C₁-C₅ alkyl group.
